(19) United States
(12) Patent Application Publication
(10) Pub. No.: US 2026/0229171 A1
(43) Pub. Date: Aug. 6, 2026

(54) DISPLAY PANEL AND DISPLAY APPARATUS

(71) Applicant: XIAMEN TIANMA DISPLAY TECHNOLOGY CO., LTD., Xiamen (CN)

(72) Inventors: Bing WANG, Xiamen (CN); Sungwook CHANG, Xiamen (CN); Sangwon LEE, Xiamen (CN)

(21) Appl. No.: 19/631,045

(22) Filed: Mar. 27, 2026

(30) Foreign Application Priority Data
Dec. 5, 2025 (CN) 202511825108.9

(51) Int. Cl. G09G 3/32; G09G 3/3233

(52) U.S. Cl. CPC G09G 3/32; G09G 3/3233; G09G 2300/043; G09G 2300/0819; G09G 2310/08; G09G 2320/0233; G09G 2330/023

(57) ABSTRACT

Provided are a display panel and a display apparatus. The display panel includes a plurality of pixel circuits and a plurality of light-emitting devices, and the light-emitting devices are connected to the pixel circuits. Each of the pixel circuits includes a driving transistor, a data writing transistor, a threshold compensation transistor, and a gate reset transistor. An active layer of the driving transistor contains silicon. The gate reset transistor is electrically connected to a second electrode of the driving transistor, and an active layer of the gate reset transistor contains metal oxide. Alternatively, an active layer of an electrode reset transistor contains metal oxide. The present disclosure can raise a voltage of a low-level signal required for controlling a transistor, such that a difference between a high-level signal and the low-level signal required for controlling the transistor decreases, thereby reducing power consumption.

### CROSS-REFERENCE TO RELATED APPLICATION

The present application claims priority to Chinese Patent Application No. 202511825108.9, filed on Dec. 5, 2025, the content of which is incorporated herein by reference in its entirety.

### TECHNICAL FIELD

The present disclosure relates to the field of display technologies and, in particular, to a display panel and a display apparatus.

### BACKGROUND

A pixel circuit and a light-emitting device are provided in a display panel, the pixel circuit is connected to the light-emitting device, and a driving transistor in the pixel circuit provides a driving current to the light-emitting device, so as to control the light-emitting device to display different gray scale brightness. Currently, a metal oxide transistor with low leakage current is generally used in a pixel circuit to connect to a gate of a driving transistor, that is, the transistor connected to the gate of the driving transistor is set as an n-type transistor, while the driving transistor and other transistors are p-type transistors, thereby achieving low-frequency driving. Since the turning on and off of a transistor need to satisfy certain conditions, control of some transistors in the above pixel circuit requires a relatively higher high level and a relatively lower low level, which increases power consumption of a display driver chip.

### SUMMARY

Embodiments of the present disclosure provide a display panel and a display apparatus, to solve a problem in the related art that driving a pixel circuit to operate leads to increased power consumption of a display driver chip.

In a first aspect, an embodiment of the present disclosure provides a display panel, including: a plurality of pixel circuits and a plurality of light-emitting devices, and the light-emitting devices are connected to the pixel circuits. Each of the pixel circuits includes a driving transistor, a data writing transistor, a threshold compensation transistor, and a gate reset transistor. The data writing transistor is electrically connected to a first electrode of the driving transistor, the threshold compensation transistor is connected between a gate and a second electrode of the driving transistor, and the gate reset transistor is electrically connected to the second electrode of the driving transistor. An operating cycle of each of the pixel circuits includes a data writing stage and a gate reset stage. In the gate reset stage, the gate reset transistor and the threshold compensation transistor are turned on, a first reset signal is written into the gate of the driving transistor, and a voltage value of the first reset signal is negative. In the data writing stage, the data writing transistor and the threshold compensation transistor are turned on, and a data voltage is written into the gate of the driving transistor. An active layer of the driving transistor contains silicon, and an active layer of the gate reset transistor contains metal oxide.

In a second aspect, based on the same inventive concept, an embodiment of the present disclosure provides a display panel, including a plurality of pixel circuits and a plurality of light-emitting devices, and the light-emitting devices are connected to the pixel circuits. Each of the pixel circuits includes a driving transistor, a data writing transistor, a threshold compensation transistor, a gate reset transistor, and an electrode reset transistor. The data writing transistor is electrically connected to a first electrode of the driving transistor, the threshold compensation transistor is connected between a gate and a second electrode of the driving transistor, the gate reset transistor is electrically connected to the gate of the driving transistor, and the electrode reset transistor is electrically connected to a first electrode of a respective one of the light-emitting devices. An operating cycle of each of the pixel circuits includes an electrode reset stage, a gate reset stage, and a data writing stage. In the gate reset stage, the gate reset transistor is turned on, a first reset signal is written into the gate of the driving transistor, and a voltage value of the first reset signal is negative. In the electrode reset stage, the electrode reset transistor is turned on, a second reset signal is written into the first electrode of one of the light-emitting devices, and a voltage value of the second reset signal is negative. In the data writing stage, the data writing transistor and the threshold compensation transistor are turned on, and a data voltage is written into the gate of the driving transistor. An active layer of the driving transistor contains silicon, and an active layer of the electrode reset transistor and an active layer of the gate reset transistor contain metal oxide.

In a third aspect, based on the same inventive concept, an embodiment of the present disclosure provides a display apparatus, including the display panel according to any one of the embodiments.

The display panel and the display apparatus according to the embodiments of the present disclosure have the following advantages: in some embodiments of the present disclosure, considering an impact of a voltage required for controlling a switching state of the gate reset transistor on power consumption, the active layer of the gate reset transistor is set to contain metal oxide. In some other embodiments, considering an impact of a voltage required for controlling a switching state of the electrode reset transistor on power consumption, the active layer of the electrode reset transistor is set to contain metal oxide. The present disclosure can break a requirement limit of a lower low-level signal for controlling an on state of certain transistors in the related art, and raises a voltage value of a low-level signal required for controlling a transistor. Without adjusting types of other transistors in the pixel circuit, a high-level voltage value of a control signal required by the pixel circuit remains unchanged, while the low-level voltage value of the required control signal is raised, such that a difference between a high-level signal and a low-level signal required for driving the pixel circuit decreases, thereby reducing power consumption. In addition, by raising the voltage of the low-level signal required for controlling the transistor, an integrated power management chip does not need to receive an extra power supply when driving the pixel circuit to operate, and the high-level signal and the low-level signal required for controlling the transistor can be generated by using an analog voltage of the display driver chip itself, and power consumption of the integrated power management chip is also reduced. Meanwhile, the number of assemblies in the integrated power management chip is also reduced, which can further reduce manufacturing costs.

### BRIEF DESCRIPTION OF DRAWINGS

To clearly illustrate the technical solutions of the embodiments of the present disclosure or the related art, the drawings required in the embodiments or the related art are briefly introduced below. It is appreciated that the drawings described below are only some embodiments of the present disclosure. For those skilled in the art, other drawings can be obtained according to these drawings without any creative effort.

FIG. 1 is a schematic diagram of a pixel circuit in the related art;

FIG. 2 is a schematic diagram of a pixel circuit according to an embodiment of the present disclosure;

FIG. 3 is a signal timing diagram according to an embodiment of the present disclosure;

FIG. 4 is a schematic diagram of another pixel circuit according to an embodiment of the present disclosure;

FIG. 5 is a schematic diagram of another pixel circuit according to an embodiment of the present disclosure;

FIG. 6 is another signal timing diagram according to an embodiment of the present disclosure;

FIG. 7 is another signal timing diagram according to an embodiment of the present disclosure;

FIG. 8 is another signal timing diagram according to an embodiment of the present disclosure;

FIG. 9 is a schematic diagram of another pixel circuit according to an embodiment of the present disclosure;

FIG. 10 is another signal timing diagram according to an embodiment of the present disclosure;

FIG. 11 is a schematic diagram of another pixel circuit according to an embodiment of the present disclosure;

FIG. 12 is another signal timing diagram according to an embodiment of the present disclosure;

FIG. 13 is a schematic diagram of another pixel circuit according to an embodiment of the present disclosure;

FIG. 14 is another signal timing diagram according to an embodiment of the present disclosure; and

FIG. 15 is a schematic diagram of a display apparatus according to an embodiment of the present disclosure.

### DESCRIPTION OF EMBODIMENTS

To make the objectives, technical solutions, and advantages of embodiments of the present disclosure clear, the technical solutions in the embodiments of the present disclosure are described clearly and completely below in conjunction with the accompanying drawings in the embodiments of the present disclosure. It is apparent that the described embodiments are only some, rather than all, of the embodiments of the present disclosure. Based on the embodiments of the present disclosure, all other embodiments obtained by those skilled in the art without any creative effort shall fall within the protection scope of the present disclosure.

The terms used in the embodiments of the present disclosure are only for the purpose of describing specific embodiments and are not intended to limit the present disclosure. The singular forms “a/an”, “said” and “the” used in the embodiments of the present disclosure and the claims are intended to include plural forms unless the context clearly indicates otherwise.

FIG. 1 is a schematic diagram of a pixel circuit in the related art. As shown in FIG. 1, the pixel circuit includes a first transistor T1 to an eighth transistor T8, a storage capacitor Cst, and a first node N1 to a fourth node N4. The third transistor T3 is a driving transistor, the first transistor T1 and the sixth transistor T6 are light-emitting control transistors, the second transistor T2 is a data writing transistor, the fourth transistor T4 is a threshold compensation transistor, the fifth transistor T5 and the seventh transistor T7 are reset transistors, and the eighth transistor T8 is a bias transistor. The first transistor T1 is connected to a first power supply terminal ELVDD, a light-emitting device is connected to a second power supply terminal ELVSS. Driving the pixel circuit to operate further requires a data voltage Vdata, a first reset signal VREF1, a second reset signal VREF2, a bias signal DVH, as well as a scanning signal ScanP1, a scanning signal ScanP2, a scanning signal ScanP3, a scanning signal ScanN, and a light-emitting control signal EM.

In the related art of FIG. 1, the fourth transistor T4 is an n-type transistor, and the other transistors are p-type transistors. In a first driving mode, when requiring to drive the pixel circuit to operate, a voltage of the first power supply terminal ELVDD is 4.6 V, a voltage of the second power supply terminal ELVSS is −4.0 V, a data voltage Vdata is within a range of 2 V to 6 V, both the first reset signal VREF1 and the second reset signal VREF2 are-4.0 V, and the bias signal DVH is 6.0 V. To control the second transistor T2 to be turned off, a high-level signal VGH of the scanning signal ScanP1 needs to be greater than 7 V. A source voltage of the seventh transistor T7 is −4.0 V, and to control the seventh transistor T7 to be fully turned on, a low-level signal VGL of the scanning signal ScanP2 needs to be less than −8 V. A source voltage of the fifth transistor T5 is −4.0 V, and to control the fifth transistor T5 to be fully turned on, a low-level signal VGL of the scanning signal ScanP3 also needs to be less than −8 V. However, a voltage range that can currently be supplied by a display driver chip is only −7.5 V to 7.5 V. To achieve a voltage range of −8 V to 8 V provided by the display driver chip, a manufacturing process of the display driver chip needs to be adjusted, and Header room margin, that is, physical or electrical space reserved in chip design used to ensure requirements such as signal integrity, heat dissipation, and manufacturing tolerances, is required. A voltage below −8 V must be generated by a Power Management IC (PMIC), and the low-level signal VGL is obtained by combining an analog voltage of the chip (AVDD) with an extra power supply, while voltage converter efficiency leads to increased power loss, affecting power consumption.

In a second driving mode of FIG. 1, when requiring to drive the pixel circuit to operate, a voltage of the first power supply terminal ELVDD is 2.8 V, a voltage of the second power supply terminal ELVSS is −5.8 V, a data voltage Vdata is within a range of 1 V to 6 V, the first reset signal VREF1 is −5.0 V, the second reset signal VREF2 is −5.8 V, and the bias signal DVH is 6.0 V. To control the second transistor T2 to be turned off, the high-level signal VGH of the scanning signal ScanP1 needs to be greater than 7 V. A source voltage of the seventh transistor T7 is −5.8 V, and to control the seventh transistor T7 to be fully turned on, the low-level signal VGL of the scanning signal ScanP2 needs to be less than −9.8 V. In this case, a voltage of the low-level signal VGL required to control the seventh transistor T7 to be turned on is lower, and the low-level signal VGL must also be generated by combining the AVDD with an extra power supply, while the voltage converter efficiency also leads to increased power loss, affecting power consumption.

Based on problems existing in the related art, in embodiments of the present disclosure, types of transistors in a pixel circuit are cooperatively designed to raise a voltage of a low-level signal required for controlling a transistor, such that a difference between a high-level signal and a low-level signal required for controlling the transistor decreases, thereby reducing power consumption. In addition, by raising the voltage of the low-level signal required for controlling the transistor, an integrated power management chip does not need to receive an extra power supply when driving the pixel circuit to operate, and the high-level signal and the low-level signal required for controlling the transistor can be generated by using an analog voltage of the display driver chip itself, and power consumption of the integrated power management chip is also reduced. The above is the main technical idea of the present disclosure, and the present disclosure is illustrated below by examples in specific embodiments.

An embodiment of the present disclosure provides a display panel, including a plurality of pixel circuits and a plurality of light-emitting devices, and the light-emitting devices are connected to the pixel circuits. The light-emitting device may be, for example, an organic light-emitting diode or an inorganic light-emitting diode. The pixel circuit is configured to drive the light-emitting device to emit light to display different gray scale brightness.

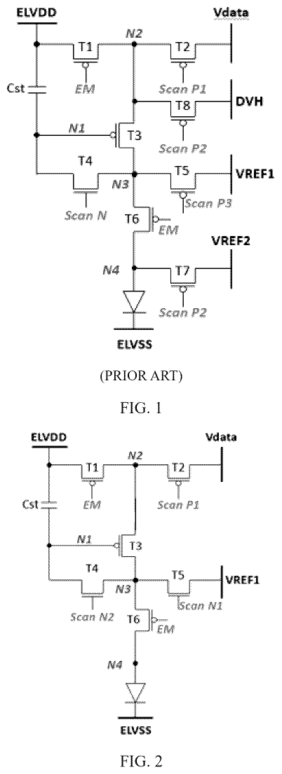

FIG. 2 is a schematic diagram of a pixel circuit according to an embodiment of the present disclosure. As shown in FIG. 2, the pixel circuit includes a driving transistor T3, a data writing transistor T2, a threshold compensation transistor T4, a gate reset transistor T5, a first light-emitting control transistor T1 and a second light-emitting control transistor T6, and a storage capacitor Cst. A gate of the driving transistor T3 is connected to a first node N1, a first electrode is connected to a second node N2, and a second electrode is connected to a third node N3. A first electrode of the data writing transistor T2 receives a data voltage Vdata, and a second electrode is electrically connected to the first electrode of the driving transistor T3. The threshold compensation transistor T4 is connected between the gate and the second electrode of the driving transistor T3. A first electrode of the gate reset transistor T5 receives a first reset signal VREF1, and a second electrode is electrically connected to the second electrode of the driving transistor T3. For the first light-emitting control transistor T1 and the second light-emitting control transistor T6, the first light-emitting control transistor T1 is connected between a first power supply terminal ELVDD and the first electrode of the driving transistor T3, and the second light-emitting control transistor T6 is connected between the second electrode of the driving transistor T3 and a first electrode of the light-emitting device. A second electrode of the light-emitting device is connected to a second power supply terminal ELVSS. Gates of the first light-emitting control transistor T1 and the second light-emitting control transistor T6 are connected to a light-emitting control signal EM, a gate of the data writing transistor T2 receives a scanning signal ScanP1, a gate of the gate reset transistor T5 receives a scanning signal ScanN1, and a gate of the threshold compensation transistor T4 receives a scanning signal ScanN2.

An active layer of the driving transistor T3 contains silicon, such as low-temperature poly-silicon, and the driving transistor T3 is a p-type transistor. An active layer of the gate reset transistor T5 contains metal oxide, such as indium gallium zinc oxide, and the gate reset transistor T5 is an n-type transistor.

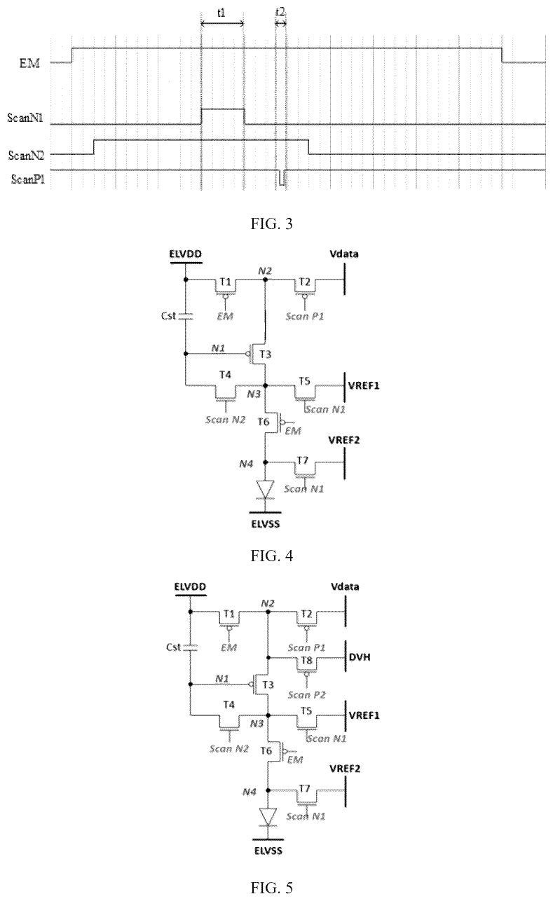

FIG. 3 is a signal timing diagram according to an embodiment of the present disclosure. The signal timing provided in FIG. 3 can be used to drive the pixel circuit in FIG. 2. Referring to FIG. 2 and FIG. 3, an operating cycle of the pixel circuit includes a gate reset stage t1 and a data writing stage t2. In the gate reset stage t1, the scanning signal ScanN1 provides an effective level to control the gate reset transistor T5 to be turned on, the scanning signal ScanN2 provides an effective level to control the threshold compensation transistor T4 to be turned on, the first reset signal VREF1 is written into the gate of the driving transistor T3 to reset the gate of the driving transistor T3, and a voltage value of the first reset signal VREF1 is negative. In the data writing stage t2, the scanning signal ScanP1 provides an effective level to control the data writing transistor T2 to be turned on, the scanning signal ScanN2 provides an effective level to control the threshold compensation transistor T4 to be turned on, and the data voltage Vdata is written into the gate of the driving transistor T3.

The display panel according to an embodiment of the present disclosure includes a pixel circuit. In the pixel circuit, the data writing transistor T2 is connected to the first electrode of the driving transistor T3, the threshold compensation transistor T4 is connected between the gate and the second electrode of the driving transistor T3, and the gate reset transistor T5 is connected to the second electrode of the driving transistor T3. Moreover, the driving transistor T3 is a p-type transistor and the gate reset transistor T5 is an n-type transistor. In the gate reset stage t1, the gate reset transistor T5 and the threshold compensation transistor T4 are turned on to reset the gate of the driving transistor T3. In a data writing stage t2, the data writing transistor T2 and the threshold compensation transistor T4 are turned on, the data voltage Vdata is written into the gate of the driving transistor T3 for self-checking and compensation of a threshold voltage of the driving transistor T3. In the pixel circuit, the gate reset transistor T5 is not directly connected to the gate of the driving transistor T3, thus a leakage current of the gate reset transistor T5 in an off state has no impact on a gate potential of the driving transistor T3. Therefore, there is no need to consider the problem of the leakage current of the gate reset transistor T5 to design the type of the gate reset transistor T5. In some embodiments of the present disclosure, considering an impact of a voltage required for controlling a switching state of the gate reset transistor T5 on power consumption, the gate reset transistor T5 is set as an n-type transistor.

In some embodiments of the present disclosure, the driving transistor T3 is a p-type transistor, and in order to reset the gate of the driving transistor T3, it is necessary to set the voltage value of the first reset signal VREF1 received by the first electrode of the gate reset transistor T5 to be negative. When the gate reset transistor T5 is a p-type transistor, the threshold voltage Vth of the p-type transistor is a negative value, and it can be turned on only when Vgs<Vth is satisfied, where Vgs represents a gate-source voltage difference of the transistor. Vgs=Vg−Vs, Vg represents a gate voltage of the transistor, and Vs represents a source voltage of the transistor. Since the voltage value of the first reset signal VREF1 is negative, that is, the source voltage of the gate reset transistor T5 is negative, the gate of the gate reset transistor T5 needs to receive a lower low-level signal to satisfy a turn-on adjustment of the gate reset transistor T5. However, the voltage value of the low-level signal of the scanning signal received by the gate of the gate reset transistor T5 is too low, leading to the integrated power management chip needing to cooperate with an extra power supply to generate a lower low-level signal, which inevitably leads to an increase in power consumption.

In some embodiments of the present disclosure, the gate reset transistor T5 is set as an n-type transistor, the threshold voltage Vth of the n-type transistor is a positive value, and it is turned on when Vgs>Vth is satisfied. The gate of the gate reset transistor T5 receives a high-level signal to control the gate reset transistor T5 to be turned on. Since the voltage value of the first reset signal VREF1 is negative, that is, the source voltage of the gate reset transistor T5 is negative, the voltage value of the high-level signal received by the gate of the gate reset transistor T5 does not need to be excessively large.

In some embodiments of the present disclosure, considering the impact of the voltage required for controlling the switching state of the gate reset transistor T5 on power consumption, the active layer of the gate reset transistor T5 is set to contain metal oxide, which breaks the requirement limit of a lower low-level signal for controlling the on state of the gate reset transistor T5 in the related art, and a voltage value of a high-level signal required for controlling the gate reset transistor T5 to be turned on does not need to be excessively large, which is equivalent to raising the voltage value of the low-level signal required for controlling the transistor. Without adjusting types of other transistors in the pixel circuit, the high-level voltage value of the control signal required by the pixel circuit remains unchanged, while the low-level voltage value of the required control signal is raised, such that the difference between the high-level signal and the low-level signal required for driving the pixel circuit decreases, thereby reducing power consumption. In addition, by raising the voltage of the low-level signal required for controlling the transistor, the integrated power management chip does not need to receive an extra power supply when driving the pixel circuit to operate, and the high-level signal and the low-level signal required for controlling the transistor can be generated by using the analog voltage of the display driver chip itself, and power consumption of the integrated power management chip is also reduced. Meanwhile, the number of components in the integrated power management chip is also reduced, which can further reduce manufacturing costs.

In some embodiments, as shown in FIG. 2, the active layer of the threshold compensation transistor T4 contains metal oxide, such as indium gallium zinc oxide. That is, the threshold compensation transistor T4 is an n-type transistor. Such a setting makes a leakage current of the threshold compensation transistor T4 in the off state small, which can improve stability of the gate potential of the driving transistor T3, and thus improve brightness stability of the light-emitting device. Especially during low-frequency display, the display panel includes a writing frame and a holding frame. The data voltage is written into the gate of the driving transistor only in the writing frame, and the display effect of the display panel in a low-frequency display mode can be improved in the holding frame.

Referring to FIG. 2 and FIG. 3, the threshold compensation transistor T4 is reused in the threshold compensation stage t1 and the data writing stage t2. The high-level signal of the scanning signal ScanN2 controls the threshold compensation transistor T4 to be turned on in the threshold compensation stage t1, and controls the threshold compensation transistor T4 to be turned on in the data writing stage t2. A high-level effective pulse of the scanning signal ScanN2 covers the threshold compensation stage t1 and the data writing stage t2 of the operating of the pixel circuit. When driving the pixel circuit to operate, setting the scanning signal ScanN2 to have one effective level pulse makes the number of signal inversions of the scanning signal ScanN2 reduced, which is beneficial to reducing power consumption.

As shown in FIG. 2, the pixel circuit includes the first light-emitting control transistor T1 and the second light-emitting control transistor T6. The first light-emitting control transistor T1 is connected between the first power supply terminal and the first electrode of the driving transistor T3, and the second light-emitting control transistor T6 is connected between the second electrode of the driving transistor T3 and the first electrode of the light-emitting device. The operating cycle of the pixel circuit further includes a light-emitting stage, which is subsequent to the data writing stage t2 and is not shown in the timing of FIG. 3. In the light-emitting stage, the light-emitting control signal EM provides an effective level to control the first light-emitting control transistor T1 and the second light-emitting control transistor T6 to be turned on, and the driving transistor T3 generates a driving current under control of its gate potential, thereby controlling the light-emitting device to emit light.

In some other embodiments, FIG. 4 is a schematic diagram of another pixel circuit according to an embodiment of the present disclosure. As shown in FIG. 4, the pixel circuit includes the driving transistor T3, the data writing transistor T2, the threshold compensation transistor T4, the gate reset transistor T5, the first light-emitting control transistor T1 and the second light-emitting control transistor T6, and the storage capacitor Cst. The pixel circuit includes the electrode reset transistor T7, a first electrode of the electrode reset transistor T7 receives the second reset signal VREF2, and a second electrode of the electrode reset transistor T7 is electrically connected to the first electrode of the light-emitting device. The second electrode of the electrode reset transistor T7, the first electrode of the light-emitting device, and the second light-emitting control transistor T6 are connected to a fourth node N4. A voltage value of the second reset signal VREF2 is negative, an active layer of the electrode reset transistor T7 contains metal oxide, such as indium gallium zinc oxide, and the electrode reset transistor T7 is an n-type transistor. The electrode reset transistor T7 is configured to reset the first electrode of the light-emitting device.

In the related art, when a driving transistor in a pixel circuit is a p-type transistor, in order to simplify a manufacturing process, the electrode reset transistor T7 is also set as a p-type transistor. Furthermore, the function of the electrode reset transistor T7 is to reset the electrode of the light-emitting device, and there is no requirement for it to have a small leakage current. Therefore, in a case where the driving transistor is a p-type transistor and the operating performance of the pixel circuit is relatively stable, the electrode reset transistor T7 is not set as a p-type transistor, because changing a type of a transistor in an actual product inevitably changes a layout arrangement of the pixel circuit and increases difficulty of the manufacturing process.

In the embodiment of FIG. 4 of the present disclosure, the electrode reset transistor T7 and the gate reset transistor T5 are both n-type transistors, and the voltage value of the second reset signal VREF2 and the voltage value of the first reset signal VREF1 are both negative. Combined with the description of reasons and effects for setting the gate reset transistor T5 as an n-type transistor in the embodiment of FIG. 2, it can be understood that the voltage value of the second reset signal VREF2 received by the first electrode of the electrode reset transistor T7 is negative. When the electrode reset transistor T7 is a p-type transistor, a low-level signal with a relatively lower voltage value is required to control the electrode reset transistor T7 to be turned on, which increases power consumption. In some embodiments of the present disclosure, the electrode reset transistor T7 is set as an n-type transistor, the threshold voltage Vth of the n-type transistor is a positive value, and it is turned on when Vgs>Vth is satisfied. A gate of the electrode reset transistor T7 receives a high-level signal to control it to be turned on, and since the voltage value of the second reset signal VREF2 is negative, the voltage value of the high-level signal received by the gate of the electrode reset transistor T7 does not need to be excessively large. Considering an impact of a voltage required for controlling a switching state of the electrode reset transistor T7 on power consumption, the active layer of the electrode reset transistor T7 is set to contain metal oxide, which breaks a requirement limit of a lower low-level signal for controlling an on state of the electrode reset transistor T7 in the related art, and a voltage value of a high-level signal required for controlling the electrode reset transistor T7 to be turned on does not need to be excessively large, which is equivalent to raising a voltage value of a low-level signal required for controlling the transistor. Without adjusting types of other transistors in the pixel circuit, a high-level voltage value of a control signal required by the pixel circuit remains unchanged, while the low-level voltage value of the required control signal is raised, such that a difference between a high-level signal and a low-level signal required for driving the pixel circuit decreases, thereby reducing power consumption. In addition, by raising the voltage of the low-level signal required for controlling the transistor, the integrated power management chip does not need to receive an extra power supply when driving the pixel circuit to operate, and the high-level signal and the low-level signal required for controlling the transistor can be generated by using the analog voltage of the display driver chip itself, and power consumption of the integrated power management chip is also reduced. Meanwhile, the number of components in the integrated power management chip is also reduced, which can further reduce manufacturing costs.

In some embodiments, the gate of the electrode reset transistor T7 and the gate of the gate reset transistor T5 receive the same signal. FIG. 4 schematically shows that the gate of the electrode reset transistor T7 and the gate of the gate reset transistor T5 both receive the scanning signal ScanN1. Referring to the timing diagram of FIG. 3, in the gate reset stage t1, the scanning signal ScanN1 provides an effective level to control the gate reset transistor T5 to be turned on, the scanning signal ScanN2 provides an effective level to control the threshold compensation transistor T4 to be turned on, the first reset signal VREF1 is written into the gate of the driving transistor T3 to reset the gate of the driving transistor T3. Meanwhile, the scanning signal ScanN1 provides an effective level to control the electrode reset transistor T7 to be turned on, the second reset signal VREF2 is written into the first electrode of the light-emitting device to reset the first electrode of the light-emitting device. In this embodiment, setting both the electrode reset transistor T7 and the gate reset transistor T5 as n-type transistors can reduce power consumption. Meanwhile, by setting the gate of the electrode reset transistor T7 and the gate of the gate reset transistor T5 to receive the same signal, structures of the two transistors in film layers of the display panel are the same, and the two transistors can be controlled using the same control line, which is beneficial to saving the number of control lines required for driving the pixel circuit to operate and saving wiring space of the display panel.

In some embodiments, the voltage value of the first reset signal VREF1 is V1, and the voltage value of the second reset signal VREF2 is V2, where V2=V1. In this embodiment, the first electrode of the electrode reset transistor T7 and the first electrode of the gate reset transistor T5 can be connected to the same reset signal line, which is beneficial to reducing the number of wirings in the display panel and saving wiring space. Moreover, when V2=V1, in a case where sizes of the electrode reset transistor T7 and the gate reset transistor T5 are consistent, conditions satisfied for both to be turned on are the same. Setting both the electrode reset transistor T7 and the gate reset transistor T5 as n-type transistors can raise the voltage value of the low-level signal required for controlling the transistors. Without adjusting types of other transistors in the pixel circuit, the high-level voltage value of the control signal required by the pixel circuit remains unchanged, while the low-level voltage value of the required control signal is raised, such that the difference between the high-level signal and the low-level signal required for driving the pixel circuit decreases, thereby reducing power consumption.

In some embodiments, when driving the pixel circuit to operate, a voltage of the first power supply terminal ELVDD is 4.6 V, a voltage of the second power supply terminal ELVSS is −4.0 V, the data voltage Vdata is within a range of 2 V to 6 V, and both the first reset signal VREF1 and the second reset signal VREF2 are −4.0 V. That is, V2=V1.

In some embodiments, the voltage value of the first reset signal VREF1 is V1, and the voltage value of the second reset signal VREF2 is V2, where V2<V1. In this embodiment, different voltages are used to reset the gate of the driving transistor T3 and the electrode of the light-emitting device. Providing a relatively higher reset voltage to the gate of the driving transistor T3 can make threshold capturing of the gate of the driving transistor T3 faster. When applied in high-frequency display or low gray scale display, a threshold capturing time of the gate of the driving transistor T3 is shorter and threshold capturing is more accurate, which can improve a display non-uniformity problem. Meanwhile, providing a relatively lower voltage to the electrode of the light-emitting device for resetting can mitigate unintended light emission of the light-emitting device and improve a low gray scale display effect.

In some embodiments, when driving the pixel circuit to operate, the voltage of the first power supply terminal ELVDD is 2.8 V, the voltage of the second power supply terminal ELVSS is −5.8 V, the data voltage Vdata is within the range of 1 V to 6 V, the first reset signal VREF1 is −5.0 V, and the second reset signal VREF2 is −5.8 V. That is, V2<V1.

Since V2<V1, when the electrode reset transistor T7 and the gate reset transistor T5 are both p-type transistors, both are turned on only when a control signal is a low-level signal and Vgs <Vth is satisfied. Compared to the gate reset transistor T5, a voltage value of a low-level signal required to control the electrode reset transistor T7 to be turned on is lower. That is, the voltage required to control the electrode reset transistor T7 to be turned on has a greater impact on power consumption. In some embodiments, in order to reduce the impact of the voltage required for controlling the electrode reset transistor T7 to be turned on on power consumption, the active layer of the electrode reset transistor T7 is set to contain metal oxide, thereby raising a voltage value of a signal required for the electrode reset transistor T7. There is no need to set a lower low-level signal for the electrode reset transistor T7, which can decrease the difference between the high-level signal and the low-level signal required for driving the pixel circuit, thereby reducing power consumption. On a basis of setting the active layer of the electrode reset transistor T7 to contain metal oxide, the active layer of the gate reset transistor T5 is also set to contain metal oxide, such that the gate reset transistor T5 and the electrode reset transistor T7 are transistors of the same type, and control terminals of both can receive the same signal. One control line can be provided in the display panel to control the gate reset transistor T5 and the electrode reset transistor T7, thereby saving wiring space in the display panel.

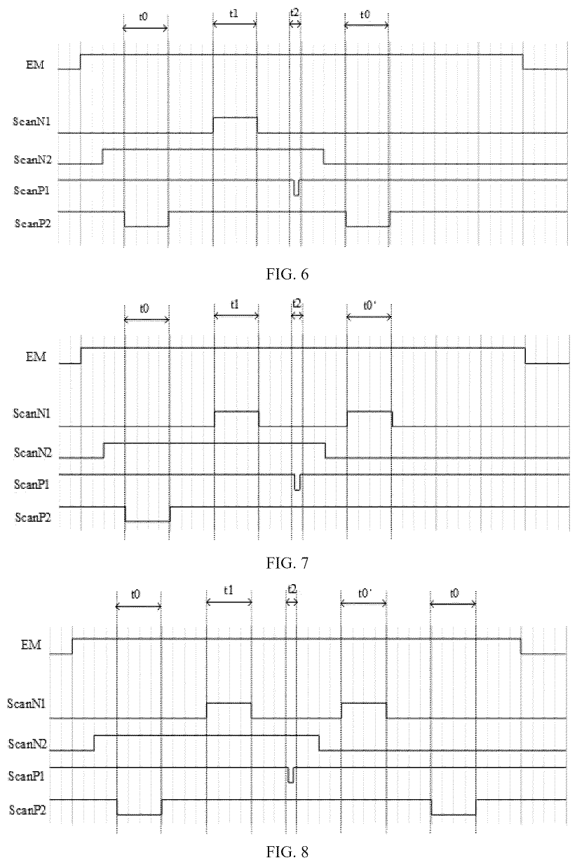

In some embodiments, FIG. 5 is a schematic diagram of another pixel circuit according to an embodiment of the present disclosure. FIG. 6 is another signal timing diagram according to an embodiment of the present disclosure. As shown in FIG. 5, the pixel circuit further includes a bias adjustment transistor T8, an active layer of the bias adjustment transistor T8 contains silicon, and the bias adjustment transistor T8 is a p-type transistor. The bias adjustment transistor T8 is electrically connected to the first electrode or the second electrode of the driving transistor T3. FIG. 5 schematically shows that a gate of the bias adjustment transistor T8 receives a scanning signal ScanP2, a first electrode receives a bias voltage DVH, and a second electrode is connected to the first electrode of the driving transistor T3.

Referring to FIG. 6, the operating cycle of the pixel circuit further includes a bias stage t0. In the bias stage t0, the bias adjustment transistor T8 is turned on, and the bias voltage DVH is written into the first electrode or the second electrode of the driving transistor T3. In this embodiment, the pixel circuit further includes the bias adjustment transistor T8, and the bias adjustment transistor T8 can be configured to adjust a bias state of the driving transistor T3, improving a threshold shift caused by the driving transistor T3 being in a forward bias state for a long time, which can improve display uniformity.

In some embodiments, in the operating cycle of the pixel circuit, at least one bias stage t0 is executed prior to the gate reset stage t1, or at least one bias stage t0 is executed subsequent to the data writing stage t2. In the bias stage t0, the scanning signal ScanP2 provides an effective level to control the bias adjustment transistor T8 to be turned on, and the bias voltage DVH is written into the first electrode or the second electrode of the driving transistor T3. The setting of the bias stage t0 does not affect the gate reset stage t1 and the data writing stage t2.

In some embodiments, as shown in FIG. 6, in the operating cycle of the pixel circuit, at least one bias stage t0 is executed prior to the gate reset stage t1, and at least one bias stage t0 is executed subsequent to the data writing stage t2. By setting the number of effective pulses of the scanning signal ScanP2, the operating cycle of the pixel circuit may include two or more bias stages t0. Reasonably configuring two or more bias stages t0 within the operating cycle of the pixel circuit can increase time for bias adjustment and improve an effect of adjusting the bias state of the driving transistor T3.

In some embodiments, FIG. 7 is another signal timing diagram according to an embodiment of the present disclosure. The signal timing provided in FIG. 7 can drive the pixel circuit provided in FIG. 5. As shown in FIG. 7, the operating cycle of the pixel circuit includes a gate reset stage t1, a data writing stage t2, and an auxiliary bias stage t0′.

In the gate reset stage t1, the scanning signal ScanN1 provides an effective level to control the gate reset transistor T5 to be turned on, the scanning signal ScanN2 provides an effective level to control the threshold compensation transistor T4 to be turned on, the first reset signal VREF1 is written into the gate of the driving transistor T3 to reset the gate of the driving transistor T3, and the voltage value of the first reset signal VREF1 is negative.

In the data writing stage t2, the scanning signal ScanP1 provides an effective level to control the data writing transistor T2 to be turned on, the scanning signal ScanN2 provides an effective level to control the threshold compensation transistor T4 to be turned on, and the data voltage Vdata is written into the gate of the driving transistor T3.

In the auxiliary bias stage t0′, the gate reset transistor T5 is turned on, the threshold compensation transistor T4 is turned off, and an auxiliary bias voltage is written into the second electrode of the driving transistor T3.

FIG. 5 schematically shows that in the operating cycle of the pixel circuit, at least one auxiliary bias stage t0′ is executed subsequent to the data writing stage t2. In this embodiment, the auxiliary bias stage t0′ is provided, and in the auxiliary bias stage t0′, the gate reset transistor T5 is configured to adjust the bias state of the driving transistor T3, so as to improve the threshold shift caused by the driving transistor T3 being in the forward bias state for a long time. The gate reset transistor T5 can reset the gate of the driving transistor T3 in the gate reset stage t1 and can also adjust the bias state of the driving transistor T3 in the auxiliary bias stage t0′. One transistor is reused in two stages, and the pixel circuit has high integration level. Only the timing of the scanning signal received by the gate of the gate reset transistor T5 needs to be adjusted to achieve the reuse of the gate reset transistor T5 in two stages. For example, as shown in FIG. 6, the scanning signal ScanN1 includes two effective level pulses, such that the gate reset transistor T5 is respectively turned on in the gate reset stage t1 and the auxiliary bias stage t0′.

In some embodiments, the first reset signal VREF1 is reused as the auxiliary bias voltage. In the display panel, the first electrode of the gate reset transistor T5 is set to be connected to the reset signal line, and the first reset signal VREF1 is reused as the auxiliary bias voltage. There is no need to adjust the voltage on the reset signal line during operating of the pixel circuit, and a signal supply method is simpler.

In some embodiments, taking the timing shown in FIG. 7 as an example, the gate of the gate reset transistor T5 receives a first control signal, and the scanning signal ScanN1 is the first control signal. In the operating cycle of the pixel circuit, the first control signal provides at least two effective pulses. In the gate reset stage t1, the first control signal provides one effective pulse to control the gate reset transistor T5 to be turned on. In the auxiliary bias stage t0′, the first control signal provides one effective pulse to control the gate reset transistor T5 to be turned on. By adjusting the timing of the scanning signal received by the gate of the gate reset transistor T5, the reuse of the gate reset transistor T5 in two stages can be achieved.

In some embodiments, at least one auxiliary bias stage t0′ is executed prior to the gate reset stage t1. In the auxiliary bias stage t0′, the gate reset transistor T5 is turned on and the threshold compensation transistor T4 is turned off, and an auxiliary bias voltage is written into the second electrode of the driving transistor T3. That is, prior to the gate reset stage t1, a period in which a high-level effective pulse of the scanning signal ScanN1 overlaps with a low level of the scanning signal ScanN2 may be set as the auxiliary bias stage t0′. The auxiliary bias stage t0′ is added prior to the gate reset stage t1 to improve a bias adjustment effect on the driving transistor T3. In one or more embodiments, the number of effective pulses of the scanning signal ScanN1 may be increased such that at least one auxiliary bias stage t0′ is executed prior to the gate reset stage t1, or the width of the effective pulse of the scanning signal ScanN1 may be increased such that the effective pulse of the scanning signal ScanN1 covers the auxiliary bias stage t0′ and the gate reset stage t1.

In some other embodiments, at least one auxiliary bias stage t0′ is executed prior to the gate reset stage t1, and at least one auxiliary bias stage t0′ is executed subsequent to the data writing stage t2. This enables full utilization of the operating cycle of the pixel circuit, and increasing the number of auxiliary bias stages t0′ improves the bias adjustment effect on the driving transistor T3.

In some other embodiments, FIG. 8 is another signal timing diagram according to an embodiment of the present disclosure. The signal timing provided in FIG. 8 can be used to drive the pixel circuit according to the embodiment of FIG. 5. As shown in FIG. 8, the operating cycle of the pixel circuit includes the gate reset stage t1, the data writing stage t2, the bias stage t0, and the auxiliary bias stage t0′. In the bias stage t0, the bias adjustment transistor T8 is turned on, and the bias voltage DVH is written into the first electrode or the second electrode of the driving transistor T3. In the auxiliary bias stage t0′, the gate reset transistor T5 is turned on and the threshold compensation transistor T4 is turned off, the auxiliary bias voltage is written into the second electrode of the driving transistor T3. It can be seen from the timing in FIG. 8 that the bias stage t0 does not overlap with the auxiliary bias stage t0′ in time. This can ensure effects of the two types of bias stages and avoid mutual interference.

The timing in FIG. 8 shows that the bias stage t0 and the auxiliary bias stage t0′ are provided subsequent to the data writing stage t2, and the auxiliary bias stage t0′ is subsequent to the data writing stage t2 and prior to the bias stage t0. In some embodiments, the bias stage t0 and the auxiliary bias stage t0′ are provided subsequent to the data writing stage t2, and the bias stage t0 is subsequent to the data writing stage t2 and prior to the auxiliary bias stage t0′.

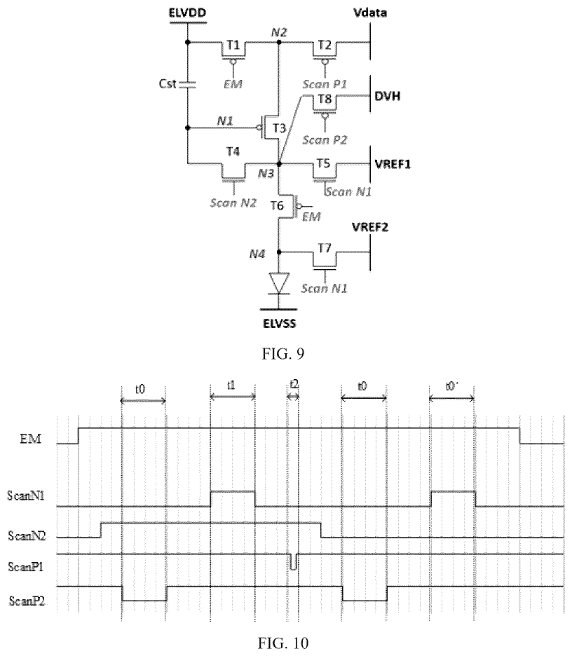

FIG. 9 is a schematic diagram of another pixel circuit according to an embodiment of the present disclosure, and FIG. 10 is another signal timing diagram according to an embodiment of the present disclosure. The signal timing provided in FIG. 10 can be used to drive the pixel circuits provided in FIG. 5 and FIG. 9. As shown in FIG. 9, the pixel circuit includes the bias adjustment transistor T8, the active layer of the bias adjustment transistor T8 contains silicon, and the bias adjustment transistor T8 is a p-type transistor. The gate of the bias adjustment transistor T8 receives the scanning signal ScanP2, the first electrode receives the bias voltage DVH, and the second electrode is connected to the second electrode of the driving transistor T3.

The timing in FIG. 10 shows that the operating cycle of the pixel circuit includes the gate reset stage t1, the data writing stage t2, the bias stage t0, and the auxiliary bias stage t0′. The bias stage t0 and the auxiliary bias stage t0′ are provided subsequent to the data writing stage t2, and the bias stage t0 is subsequent to the data writing stage t2 and prior to the auxiliary bias stage t0′.

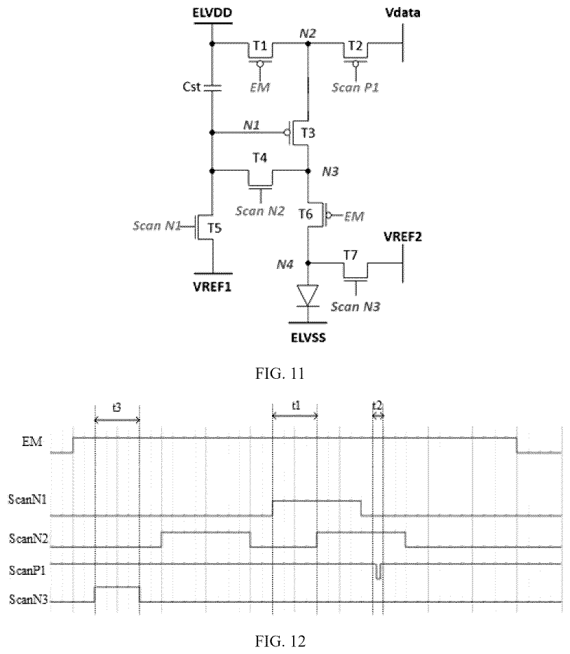

Based on the same inventive concept, an embodiment of the present disclosure provides another pixel circuit. The pixel circuit may be applied in a display panel, and a light-emitting device is set to be connected to the pixel circuit. FIG. 11 is a schematic diagram of another pixel circuit according to an embodiment of the present disclosure. As shown in FIG. 11, the pixel circuit includes the driving transistor T3, the data writing transistor T2, the threshold compensation transistor T4, the gate reset transistor T5, and the electrode reset transistor T7. The gate of the driving transistor T3 is connected to the first node N1, the first electrode is connected to the second node N2, and the second electrode is connected to the third node N3. The first electrode of the data writing transistor T2 receives the data voltage Vdata, and the second electrode is electrically connected to the first electrode of the driving transistor T3. The threshold compensation transistor T4 is connected between the gate and the second electrode of the driving transistor T3, the first electrode of the gate reset transistor T5 receives the first reset signal VREF1, the second electrode of the gate reset transistor T5 is connected to the gate of the driving transistor T3, the first electrode of the electrode reset transistor T7 receives the second reset signal VREF2, and the second electrode of the electrode reset transistor T7 is connected to the first electrode of the light-emitting device. The active layer of the driving transistor T3 contains silicon, and the active layer of the electrode reset transistor T7 and the active layer of the gate reset transistor T5 contain metal oxide. The driving transistor T3 is a p-type transistor, and the electrode reset transistor T7 and the gate reset transistor T5 are n-type transistors.

The gate of the data writing transistor T2 receives the scanning signal ScanP1, the gate of the gate reset transistor T5 receives the scanning signal ScanN1, the gate of the threshold compensation transistor T4 receives the scanning signal ScanN2, and the gate of the electrode reset transistor T7 receives the scanning signal ScanN3. Driving the pixel circuit to operate further requires the first power supply terminal ELVDD and the second power supply terminal ELVSS.

FIG. 12 is another signal timing diagram according to an embodiment of the present disclosure. The signal timing in FIG. 12 can be used to drive the pixel circuit in FIG. 11. Referring to FIG. 11 and FIG. 12, the operating cycle of the pixel circuit includes an electrode reset stage t3, the gate reset stage t1, and the data writing stage t2.

In the gate reset stage t1, the scanning signal ScanN1 provides an effective level to control the gate reset transistor T5 to be turned on, the first reset signal VREF1 is written into the gate of the driving transistor T3, and the voltage value of the first reset signal VREF1 is negative. In the electrode reset stage t3, the scanning signal ScanN3 provides an effective level to control the electrode reset transistor T7 to be turned on, the second reset signal VREF2 is written into the first electrode of the light-emitting device, and the voltage value of the second reset signal VREF2 is negative. In the data writing stage t2, the scanning signal ScanP1 provides an effective level to control the data writing transistor T2 to be turned on, the scanning signal ScanN2 provides an effective level to control the threshold compensation transistor T4 to be turned on, and the data voltage is written into the gate of the driving transistor T3.

In this embodiment, the driving transistor T3 is a p-type transistor, and the electrode reset transistor T7 and the gate reset transistor T5 are n-type transistors. The gate reset transistor T5 is connected to the gate of the driving transistor T3 for resetting the gate of the driving transistor T3. The electrode reset transistor T7 is connected to the first electrode of the light-emitting device for resetting the first electrode of the light-emitting device. Since the gate reset transistor T5 is connected to the gate of the driving transistor T3, a leakage current of the gate reset transistor T5 in the off state has an impact on a gate potential of the driving transistor T3. Setting the gate reset transistor T5 as an n-type transistor can reduce the leakage current of the gate reset transistor T5 in the off state, and improve stability of the gate potential of the driving transistor T3, thereby improving brightness stability of the light-emitting device. Especially during low-frequency display, the display panel includes the writing frame and the holding frame. The data voltage is written into the gate of the driving transistor only in the writing frame, and the display effect of the display panel in a low-frequency display mode can be improved in the holding frame.

As for the electrode reset transistor T7, its function is to reset the electrode of the light-emitting device, and there is no requirement for it to have a small leakage current in the pixel circuit. Therefore, in a case where the driving transistor is a p-type transistor and the operating performance of the pixel circuit is relatively stable, the electrode reset transistor T7 is not set as a p-type transistor, because changing a type of a transistor in an actual product inevitably changes a layout arrangement of the pixel circuit and increases difficulty of the manufacturing process. In contrast, the present disclosure sets the active layer of the electrode reset transistor T7 to contain metal oxide, considering an impact of a voltage required for controlling a switching state of the electrode reset transistor T7 on power consumption.

In some embodiments of the present disclosure, the voltage value of the second reset signal VREF2 received by the first electrode of the electrode reset transistor T7 is negative. When the electrode reset transistor T7 is a p-type transistor, the threshold voltage Vth of the p-type transistor is a negative value, and it can be turned on only when Vgs<Vth is satisfied. Since the voltage value of the second reset signal VREF2 is negative, that is, a source voltage of the electrode reset transistor T7 is negative, the gate of the electrode reset transistor T7 needs to receive a lower low-level signal to satisfy a turn-on adjustment of the electrode reset transistor T7. However, a voltage value of a low-level signal of the scanning signal received by the gate of the electrode reset transistor T7 is too low, leading to the integrated power management chip needing to cooperate with an extra power supply to generate a lower low-level signal, which inevitably leads to an increase in power consumption.

In some embodiment of the present disclosure, the electrode reset transistor T7 is set as an n-type transistor, the threshold voltage Vth of the n-type transistor is a positive value, and it is turned on when Vgs>Vth is satisfied. The gate of the electrode reset transistor T7 receives a high-level signal to control the electrode reset transistor T7 to be turned on. Since the voltage value of the second reset signal VREF2 is negative, that is, the source voltage of the electrode reset transistor T7 is negative, the voltage value of the high-level signal received by the gate of the electrode reset transistor T7 does not need to be excessively large.

Considering the impact of the voltage required for controlling the switching state of the electrode reset transistor T7 on power consumption, an embodiment of the present disclosure sets the active layer of the electrode reset transistor T7 to contain metal oxide, which breaks a requirement limit of a lower low-level signal for controlling an on state of the electrode reset transistor T7 in the related art, and a voltage value of a high-level signal required for controlling the electrode reset transistor T7 to be turned on does not need to be excessively large, which is equivalent to raising the voltage value of the low-level signal required for controlling the transistor. Without adjusting types of other transistors in the pixel circuit, the high-level voltage value of the control signal required by the pixel circuit remains unchanged, while the low-level voltage value of the required control signal is raised, such that the difference between the high-level signal and the low-level signal required for driving the pixel circuit decreases, thereby reducing power consumption. In addition, by raising the voltage of the low-level signal required for controlling the transistor, the integrated power management chip does not need to receive an extra power supply when driving the pixel circuit to operate, and the high-level signal and the low-level signal required for controlling the transistor can be generated by using the analog voltage of the display driver chip itself, and power consumption of the integrated power management chip is also reduced. Meanwhile, the number of components in the integrated power management chip is also reduced, which can further reduce manufacturing costs.

Moreover, the active layers of the electrode reset transistor T7 and the gate reset transistor T5 contain metal oxide. On a basis of setting the gate reset transistor T5 as an n-type transistor to reduce its leakage current in the off state, the electrode reset transistor T7 is also set as an n-type transistor to reduce power consumption. The electrode reset transistor T7 and the gate reset transistor T5 are transistors of the same type, and the two can be manufactured using the same process, without adding a new process during manufacturing of the display panel.

As shown in FIG. 11, the pixel circuit includes the first light-emitting control transistor T1 and the second light-emitting control transistor T6, the first light-emitting control transistor T1 is connected between the first power supply terminal and the first electrode of the driving transistor T3, and the second light-emitting control transistor T6 is connected between the second electrode of the driving transistor T3 and the first electrode of the light-emitting device. The operating cycle of the pixel circuit further includes a light-emitting stage, which is subsequent to the data writing stage t2 and is not labeled in the timing of FIG. 12. In the light-emitting stage, a light-emitting control signal EM provides an effective level to control the first light-emitting control transistor T1 and the second light-emitting control transistor T6 to be turned on, and the driving transistor T3 generates a driving current under control of its gate potential, thereby controlling the light-emitting device to emit light.

In some embodiments, the active layer of the threshold compensation transistor T4 contains metal oxide. The threshold compensation transistor T4 is an n-type transistor. Such a setting makes the leakage current of the threshold compensation transistor T4 in an off state small, which can improve stability of the gate potential of the driving transistor T3, and can further improve brightness stability of the light-emitting device. Especially during low-frequency display, the display panel includes the writing frame and the holding frame, where the data voltage is written into the gate of the driving transistor only in the writing frame, and the display effect of the display panel in a low-frequency display mode can be improved in the holding frame.

In some embodiments, the voltage value of the first reset signal VREF1 is V1, and the voltage value of the second reset signal VREF2 is V2, where V2=V1. In this embodiment, the first electrode of the electrode reset transistor T7 and the first electrode of the gate reset transistor T5 can be connected to the same reset signal line, which is beneficial to reducing the number of wirings in the display panel and saving wiring space.

In an embodiment, when driving the pixel circuit to operate, the voltage of the first power supply terminal ELVDD is 4.6V, the voltage of the second power supply terminal ELVSS is −4.0 V, the data voltage Vdata is within a range of 2 V to 6 V, and both the first reset signal VREF1 and the second reset signal VREF2 are −4.0 V. That is, V2=V1.

In some embodiments, the voltage value of the first reset signal VREF1 is V1, and the voltage value of the second reset signal VREF2 is V2, where V2<V1. In this embodiment, different voltages are used to reset the gate of the driving transistor T3 and the electrode of the light-emitting device. Providing a relatively higher reset voltage to the gate of the driving transistor T3 can make threshold capturing of the gate of the driving transistor T3 faster. When applied in high-frequency display or low gray scale display, a threshold capturing time of the gate of the driving transistor T3 is shorter and threshold capturing is more accurate, which can improve a display non-uniformity problem. Meanwhile, providing a relatively lower voltage to the electrode of the light-emitting device for resetting can mitigate unintended light emission of the light-emitting device and improve a low gray scale display effect.

In one embodiment, when driving the pixel circuit to operate, the voltage of the first power supply terminal ELVDD is 2.8 V, the voltage of the second power supply terminal ELVSS is −5.8 V, the data voltage Vdata is within a range of 1 V to 6 V, the first reset signal VREF1 is −5.0 V, and the second reset signal VREF2 is −5.8 V. That is, V2<V1.

When V2<V1, when the electrode reset transistor T7 is a p-type transistor, a lower low-level signal is required to control the electrode reset transistor T7 to be turned on, thus the voltage required to control the electrode reset transistor T7 to be turned on has a greater impact on power consumption. In some embodiments, in order to reduce the impact of the voltage required for controlling the electrode reset transistor T7 to be turned on on power consumption, the active layer of the electrode reset transistor T7 is set to contain metal oxide, thereby raising a voltage value of a signal required for the electrode reset transistor T7. There is no need to set a lower low-level signal for the electrode reset transistor T7, which can decrease the difference between the high-level signal and the low-level signal required for driving the pixel circuit, thereby reducing power consumption. On a basis of setting the active layer of the gate reset transistor T5 to contain metal oxide, the active layer of the electrode reset transistor T7 is also set to contain metal oxide, such that the gate reset transistor T5 and the electrode reset transistor T7 are transistors of the same type, thus manufacturing processes of the two are the same, and no new manufacturing process needs to be added during manufacturing of the display panel.

In some embodiments, the gate of the gate reset transistor T5 receives the first control signal, the gate of the threshold compensation transistor T4 receives the second control signal, and the gate of the electrode reset transistor T7 receives the third control signal. The scanning signal ScanN1 is the first control signal, the scanning signal ScanN2 is the second control signal, and the scanning signal ScanN3 is the third control signal.

Referring to FIG. 12, in the gate reset stage t1, the first control signal provides an effective pulse to control the gate reset transistor T5 to be turned on. In the data writing stage t2, the second control signal provides an effective pulse to control the threshold compensation transistor T4 to be turned on. In the electrode reset stage, the third control signal provides an effective pulse to control the electrode reset transistor T7 to be turned on. When driving is performed using the timing of FIG. 12, in the operating cycle of the pixel circuit, the electrode reset stage t3 does not overlap with the gate reset stage t1. Although the electrode reset transistor T7 and the gate reset transistor T5 are transistors of the same type, their gates receive different control signals. That is, a separate scanning signal is used to control the electrode reset stage t3, such that a period for resetting the gate of the driving transistor T3 and a period for resetting the electrode of the light-emitting device are separated from each other. In application, the display panel may be set to have a low-frequency operating mode, and in the low-frequency operating mode, the electrode reset transistor T7 can be configured separately to reset the device electrode in the operating cycle of the pixel circuit to satisfy low-frequency driving requirements.

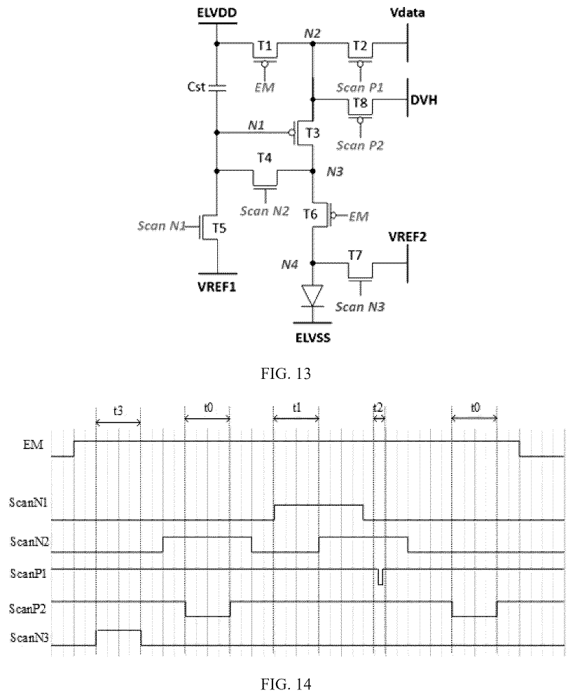

In some embodiments, FIG. 13 is a schematic diagram of another pixel circuit according to an embodiment of the present disclosure. FIG. 14 is another signal timing diagram according to an embodiment of the present disclosure, and the signal timing in FIG. 14 can be used to drive the pixel circuit in FIG. 13. As shown in FIG. 13, the pixel circuit further includes the bias adjustment transistor T8, the active layer of the bias adjustment transistor T8 contains silicon, and the bias adjustment transistor T8 is a p-type transistor. The bias adjustment transistor T8 is electrically connected to the first electrode or the second electrode of the driving transistor T3. FIG. 14 shows only that the gate of the bias adjustment transistor T8 receives the scanning signal ScanP2, the first electrode of the bias adjustment transistor T8 receives the bias voltage DVH, and the second electrode is connected to the first electrode of the driving transistor T3.

Referring to FIG. 13 and FIG. 14, the operating cycle of the pixel circuit further includes the bias stage t0. In the bias stage, the bias adjustment transistor T8 is turned on, and the bias voltage DVH is written into the first electrode or the second electrode of the driving transistor T3. In this embodiment, the pixel circuit further includes the bias adjustment transistor T8, and the bias adjustment transistor T8 can be configured to adjust the bias state of the driving transistor T3, improving a threshold shift caused by the driving transistor T3 being in a forward bias state for a long time, which can improve display uniformity.

In the operating cycle of the pixel circuit, at least one bias stage t0 is executed prior to the gate reset stage t1, and/or at least one bias stage t0 is executed subsequent to the data writing stage t2. The setting of the bias stage t0 does not affect the gate reset stage t1 and the data writing stage t2. The gate of the bias adjustment transistor T8 receives the scanning signal ScanP2, and by setting the number of effective pulses of the scanning signal ScanP2, the operating cycle of the pixel circuit may include one, two, or more bias stages t0. Reasonably configuring one, two, or more bias stages t0 within the operating cycle of the pixel circuit can increase time for bias adjustment and improve the effect of adjusting the bias state of the driving transistor T3.

As shown in FIG. 14, the operating cycle of the pixel circuit includes two bias stages t0, one bias stage t0 is prior to the gate reset stage t1, and another bias stage t0 is subsequent to the data writing stage t2. The scanning signal ScanN2 includes two effective pulses, and the scanning signal ScanP2 includes two effective pulses.

In the bias stage t0 prior to the gate reset stage t1, the scanning signal ScanP2 provides an effective pulse to control the bias adjustment transistor T8 to be turned on, and the bias voltage DVH is written into the first electrode of the driving transistor T3. Meanwhile, the scanning signal ScanN2 provides an effective level to control the threshold compensation transistor T4 to be turned on. The gate reset stage t1 has not yet been reached, thus the gate of the driving transistor T3 maintains the signal written in a previous frame, and the driving transistor T3 is turned on to make its first electrode and its second electrode conduct, such that the bias voltage DVH is written into its second electrode via the first electrode of the driving transistor T3, and then written into the gate of the driving transistor T3 via the threshold compensation transistor T4. In this stage, the bias state of the gate of the driving transistor T3 is adjusted by writing the signal into the gate of the driving transistor T3. In this bias stage, a first effective pulse of the scanning signal ScanP2 at least partially overlaps with a first effective pulse of the scanning signal ScanN2. By adjusting signal timing of the scanning signal ScanN2, the threshold compensation transistor T4 is reused in the bias stage t0 and the data writing stage t2.

In the bias stage t0 subsequent to the data writing stage t2, the scanning signal ScanP2 provides an effective pulse to control the bias adjustment transistor T8 to be turned on, and the bias voltage DVH is written into the first electrode of the driving transistor T3, so as to adjust the bias state of the gate of the driving transistor T3.

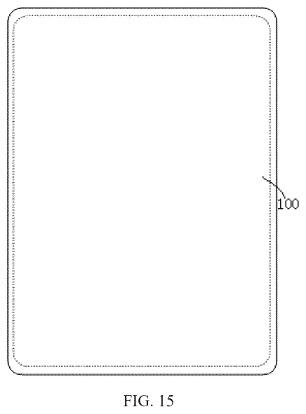

Based on the same inventive concept, an embodiment of the present disclosure further provides a display apparatus. FIG. 15 is a schematic diagram of a display apparatus according to an embodiment of the present disclosure. As shown in FIG. 15, the display apparatus includes the display panel 100 according to any one of the embodiments of the present disclosure. The display panel includes the pixel circuit according to any one of the embodiments of the present disclosure. The structure of the pixel circuit has been described in the above embodiments and will not be repeated here. The display apparatus according to the embodiment of the present disclosure may be, for example, an electronic device with a display function such as a mobile phone, a tablet, a computer, a television, and a smart wearable product.

The above description is merely preferred embodiments of the present disclosure, and is not intended to limit the present disclosure. Any modification, equivalent substitution, improvement, etc. made within the spirit and principle of the present disclosure shall fall within the protection scope of the present disclosure.

It should be noted that the above embodiments are merely used to illustrate the technical solutions of the present disclosure, rather than to limit it. Although the present disclosure has been described in detail with reference to the above embodiments, those skilled in the art should understand that they can still modify the technical solutions described in the above embodiments, or replace some or all of the technical features therein by equivalents. However, these modifications or replacements do not make the essence of the corresponding technical solutions deviate from the scope of the technical solutions of the embodiments of the present disclosure.

What is claimed is:

1. A display panel, comprising:
a pixel circuit, wherein the pixel circuit comprises a driving transistor, a data writing transistor, a threshold compensation transistor, and a gate reset transistor, the data writing transistor is electrically connected to a first electrode of the driving transistor, the threshold compensation transistor is connected between a gate of the driving transistor and a second electrode of the driving transistor, and the gate reset transistor is electrically connected to the second electrode of the driving transistor; and
a light-emitting device connected to the pixel circuit,
wherein an operating cycle of the pixel circuit comprises a data writing stage and a gate reset stage; in the gate reset stage, the gate reset transistor and the threshold compensation transistor are turned on, a first reset signal is written into the gate of the driving transistor, and a voltage value of the first reset signal is negative; and in the data writing stage, the data writing transistor and the threshold compensation transistor are turned on, and a data voltage is written into the gate of the driving transistor; and
wherein an active layer of the driving transistor contains silicon, and an active layer of the gate reset transistor contains metal oxide.

2. The display panel according to claim 1, wherein an active layer of the threshold compensation transistor contains metal oxide.

3. The display panel according to claim 1, wherein the pixel circuit comprises an electrode reset transistor, a first electrode of the electrode reset transistor is configured to receive a second reset signal, and a second electrode of the electrode reset transistor is electrically connected to a first electrode of the light-emitting device, a voltage value of the second reset signal is negative, and an active layer of the electrode reset transistor contains metal oxide.

4. The display panel according to claim 3, wherein a gate of the electrode reset transistor and a gate of the gate reset transistor are configured to receive a same signal; and
in the gate reset stage, the electrode reset transistor is turned on, and the second reset signal is written into the first electrode of the light-emitting device.

5. The display panel according to claim 3, wherein a voltage value of the first reset signal is V1, and a voltage value of the second reset signal is V2, where V2≤V1.

6. The display panel according to claim 1, wherein the pixel circuit further comprises a bias adjustment transistor, an active layer of the bias adjustment transistor contains silicon, and the bias adjustment transistor is electrically connected to the first electrode of the driving transistor or the second electrode of the driving transistor; and
the operating cycle of the pixel circuit further comprises a bias stage, and in the bias stage, the bias adjustment transistor is turned on, and a bias voltage is written into the first electrode of the driving transistor or the second electrode of the driving transistor.

7. The display panel according to claim 6, wherein during the operating cycle of the pixel circuit, at least one bias stage is executed prior to the gate reset stage, and/or at least one bias stage is executed subsequent to the data writing stage.

8. The display panel according to claim 1, wherein the operating cycle of the pixel circuit further comprises an auxiliary bias stage, in the auxiliary bias stage, the gate reset transistor is turned on, and an auxiliary bias voltage is written into the second electrode of the driving transistor; and
in the operating cycle of the pixel circuit, at least one auxiliary bias stage is executed prior to the gate reset stage, and/or at least one auxiliary bias stage is executed subsequent to the data writing stage.

9. The display panel according to claim 8, wherein the first reset signal is reused as the auxiliary bias voltage.

10. The display panel according to claim 8, wherein a gate of the gate reset transistor is configured to receive a first control signal, and during the operating cycle of the pixel circuit, the first control signal is configured to provide at least two effective pulses; and
in the gate reset stage, the first control signal is configured to provide one effective pulse to control the gate reset transistor to be turned on; and in the auxiliary bias stage, the first control signal is configured to provide one effective pulse to control the gate reset transistor to be turned on.

11. The display panel according to claim 8, wherein the operating cycle of the pixel circuit comprises a bias stage, and the bias stage does not overlap with the auxiliary bias stage.

12. The display panel according to claim 1, wherein the pixel circuit further comprises a first light-emitting control transistor and a second light-emitting control transistor, the first light-emitting control transistor is connected between a first power supply terminal and the first electrode of the driving transistor, and the second light-emitting control transistor is connected between the second electrode of the driving transistor and a first electrode of the light-emitting device; and
the operating cycle of the pixel circuit further comprises a light-emitting stage, and in the light-emitting stage, the first light-emitting control transistor and the second light-emitting control transistor are turned on, and a driving current is generated by the driving transistor under control of a gate potential of the driving transistor.

13. A display panel, comprising:
a pixel circuit, wherein the pixel circuit comprises a driving transistor, a data writing transistor, a threshold compensation transistor, a gate reset transistor, and an electrode reset transistor, the data writing transistor is electrically connected to a first electrode of the driving transistor, the threshold compensation transistor is connected between a gate of the driving transistor and a second electrode of the driving transistor, and the gate reset transistor is electrically connected to the gate of the driving transistor; and
a light-emitting device connected to the pixel circuit, wherein the electrode reset transistor is electrically connected to a first electrode of the light-emitting device,
wherein an operating cycle of the pixel circuit comprises an electrode reset stage, a gate reset stage, and a data writing stage; in the gate reset stage, the gate reset transistor is turned on, a first reset signal is written into the gate of the driving transistor, and a voltage value of the first reset signal is negative; in the electrode reset stage, the electrode reset transistor is turned on, a second reset signal is written into the first electrode of the light-emitting device, and a voltage value of the second reset signal is negative; and in the data writing stage, the data writing transistor and the threshold compensation transistor are turned on, and a data voltage is written into the gate of the driving transistor; and
wherein an active layer of the driving transistor contains silicon, and an active layer of the electrode reset transistor and an active layer of the gate reset transistor contain metal oxide.

14. The display panel according to claim 13, wherein an active layer of the threshold compensation transistor contains metal oxide.

15. The display panel according to claim 13, wherein a voltage value of the first reset signal is V1, and a voltage value of the second reset signal is V2, where V2≤V1.

16. The display panel according to claim 13, wherein the pixel circuit further comprises a bias adjustment transistor, an active layer of the bias adjustment transistor contains silicon, and the bias adjustment transistor is electrically connected to the first electrode of the driving transistor or the second electrode of the driving transistor; and
the operating cycle of the pixel circuit further comprises a bias stage, and in the bias stage, the bias adjustment transistor is turned on, and a bias voltage is written into the first electrode of the driving transistor or the second electrode of the driving transistor.

17. The display panel according to claim 16, wherein in the operating cycle of the pixel circuit, at least one bias stage is executed prior to the gate reset stage, and/or at least one bias stage is executed subsequent to the data writing stage.

18. The display panel according to claim 13, wherein a gate of the gate reset transistor is configured to receive a first control signal, a gate of the threshold compensation transistor is configured to receive a second control signal, and a gate of the electrode reset transistor is configured to receive a third control signal; and
in the gate reset stage, the first control signal is configured to provide an effective pulse to control the gate reset transistor to be turned on; in the data writing stage, the second control signal is configured to provide an effective pulse to control the threshold compensation transistor to be turned on; and in the electrode reset stage, the third control signal is configured to provide an effective pulse to control the electrode reset transistor to be turned on.

19. The display panel according to claim 13, wherein the pixel circuit further comprises a first light-emitting control transistor and a second light-emitting control transistor, the first light-emitting control transistor is connected between a first power supply terminal and the first electrode of the driving transistor, and the second light-emitting control transistor is connected between the second electrode of the driving transistor and the first electrode of the light-emitting device; and
the operating cycle of the pixel circuit further comprises a light-emitting stage, and in the light-emitting stage, the first light-emitting control transistor and the second light-emitting control transistor are turned on, and a driving current is generated by the driving transistor under control of a gate potential of the driving transistor.

20. A display apparatus, comprising a display panel,
wherein the display panel comprises:
a pixel circuit, wherein the pixel circuit comprises a driving transistor, a data writing transistor, a threshold compensation transistor, and a gate reset transistor, the data writing transistor is electrically connected to a first electrode of the driving transistor, the threshold compensation transistor is connected between a gate of the driving transistor and a second electrode of the driving transistor, and the gate reset transistor is electrically connected to the second electrode of the driving transistor; and
a light-emitting device connected to the pixel circuit,
wherein an operating cycle of the pixel circuit comprises a data writing stage and a gate reset stage; in the gate reset stage, the gate reset transistor and the threshold compensation transistor are turned on, a first reset signal is written into the gate of the driving transistor, and a voltage value of the first reset signal is negative; and in the data writing stage, the data writing transistor and the threshold compensation transistor are turned on, and a data voltage is written into the gate of the driving transistor; and
wherein an active layer of the driving transistor contains silicon, and an active layer of the gate reset transistor contains metal oxide.
